(19) United States
(12) Patent Application Publication
(10) Pub. No.: US 2022/0027534 A1
(43) Pub. Date: Jan. 27, 2022

(54) PHYSICS-PRESERVING IMPES SCHEME AND SYSTEM

(71) Applicant: KING ABDULLAH UNIVERSITY OF SCIENCE AND TECHNOLOGY, Thuwal (SA)

(72) Inventors: Shuyu SUN, Thuwal (SA); Huangxin CHEN, Thuwal (SA)

(21) Appl. No.: 17/276,204

(22) PCT Filed: Sep. 18, 2019
(86) PCT No.: PCT/IB2019/057875

§ 371 Date: Mar. 15, 2021

Related U.S. Application Data
(60) Provisional application No. 62/739,522, filed on Oct. 1, 2018.

(51) Int. Cl. G06F 30/23; G01V 99/00; E21B 47/10

(52) U.S. Cl. CPC G06F 30/23; E21B 2200/20; E21B 47/10; G01V 99/005

(57) ABSTRACT

A physics-preserving, implicit pressure, explicit saturation method for simulation of incompressible and immiscible two-phase flow in heterogeneous porous media with capillary pressure, includes receiving input data that characterizes a given domain in a subsurface of the earth; selecting initial parameters K associated with a mixed finite element algorithm; modifying Darcy flows to include a total velocity uₜ and a capillarity potential gradient ξ_{c}; establishing a total conservation equation by summing a discretized conservation equation for each phase α of the two-phase flow; and calculating at least one parameter based on the modified Darcy flows and the total conservation equation. The at least one parameter characterizes the two-phase flow in the heterogeneous porous media with a capillary pressure, between an injection well and a production well.

### CROSS-REFERENCE TO RELATED APPLICATIONS

This application claims priority to U.S. Provisional Patent Application No. 62/739,522, filed on Oct. 1, 2018, entitled “PHYSICS-PRESERVING IMPES SCHEME FOR INCOMPRESSIBLE AND IMMISCIBLE TWO-PHASE FLOW IN HETEROGENEOUS POROUS MEDIA,” the disclosure of which is incorporated herein by reference in its entirety.

### BACKGROUND

### Technical Field

Embodiments of the subject matter disclosed herein generally relate to a system and method for simulation of an incompressible and immiscible two-phase flow in heterogeneous porous media, and more particularly, to a scheme that is unbiased with regard to the two phases and the saturations of both phases are bounds-preserving when the time step size is smaller than a certain value.

### Discussion of the Background

In reservoir engineering and chemical flow, it is desired to calculate a fluid flow through a porous medium. Thus, the study of multi-component and multi-phase fluid systems plays an important role in the thorough and accurate understanding of flow behaviors in a large range of applications. For example, in reservoir engineering, when a numerical simulation is performed to estimate the amount of oil stored in the reservoir and the best way to extract that oil, it is desired to determine whether the studied fluid (e.g., oil and water) can remain in one single phase or will split into multi phases including oil gas phase, water phase, gas phase, etc. Also, it is desired to be able to calculate the productivity of such reservoir, which is achieved to be estimating the flow of oil from the reservoir.

While many approaches are known in the art for simulating the two-phase flow of various liquids, there is no physics-preserving scheme for the simulation of incompressible and immiscible two-phase flow in heterogeneous porous media with capillary pressure. Various types of numerical methods have been developed in literature to simulate two-phase flow in porous media. The fully implicit scheme [4, 12, 13, 17, 22, 27, 23, 24, 25] implicitly solves all the unknowns, and thus, it achieves unconditional stability and mass conservation for both of phases. However, the fully implicit methods require lots of computational resources for each time step.

The IMplicit-EXplicit Scheme (IMPES) [3] treats the linear terms implicitly and evaluates the others explicitly, and thus, it achieves a better stability than the fully explicit scheme. The operator splitting method [2] is another efficient approach to reduce a complex time-dependent problem into some simpler problems.

The IMPES scheme ([18], [19]) has been widely applied to solve the coupled nonlinear system for the two-phase flow in porous media [14, 26, 9, 10, 11, 7, 8], The approach of the IMPES scheme is to separate the computation of the pressure from that of the saturation, so that the pressure and saturation equations are solved using implicit and explicit time approximation schemes, respectively. The IMPES scheme is simple to set up and efficient to implement, and it requires less computer memory compared with the fully implicit schemes.

However, the IMPES scheme suffers of the following problem. For the two-phase flow in heterogeneous porous media with capillary pressure, the saturations may be discontinuous due to different capillary pressure functions, which are often a result of the heterogeneous permeability distribution. In this case, the standard IMPES scheme [18, 19] does not reproduce the correct solutions because the standard IMPES scheme always generates spatially continuous saturation, if the capillarity is present.

An improved IMPES scheme [15, 16] (HF-IMPES) was proposed to treat this problem. For different capillary pressures, the HF-IMPES scheme can reproduce the saturation solution with the expected discontinuity. However, both the standard IMPES scheme and the HF-IMPES scheme conserve the mass only for the wetting phase (i.e., they are mass-conservative for one phase), and thus, they are not mass-conservative for the total fluid mixture. This deficiency of the IMPES and HF-IMPES schemes makes them to fail sometimes when describing the fluid flow through the heterogenous porous media.

Moreover, both the standard IMPES scheme and the HF-IMPES scheme might produce a wetting-phase saturation which is larger than one, which violates the law of physics. Various kinds of improved IMPES schemes have been introduced for a better simulation of the two-phase flow in the porous media, which include the iterative IMPES scheme, the adaptive implicit techniques, etc. However, none of these schemes is a true physics-preserving IMPES scheme for the two-phase flow in heterogeneous porous media with capillary pressure, which inherently preserves the full mass conservation locally and retains the continuity of the total velocity in its normal direction.

Thus, there is a need for a new scheme that avoids the problems noted above of the traditional schemes and also is more physics-preserving IMPES scheme for the two-phase flow in heterogeneous porous media with capillary pressure.

### BRIEF SUMMARY OF THE INVENTION

According to an embodiment, there is a physics-preserving implicit pressure explicit saturation method for simulation of incompressible and immiscible two-phase flow in heterogeneous porous media with capillary pressure. The method includes receiving input data that characterizes a given domain in a subsurface of the earth; selecting initial parameters K associated with a mixed finite element algorithm; modifying Darcy flows to include a total velocity uₜ and a capillarity potential gradient ξ_{c}; establishing a total conservation equation by summing a discretized conservation equation for each phase a of the two-phase flow; and calculating at least one parameter based on the modified Darcy flows and the total conservation equation. The at least one parameter characterizes the two-phase flow in the heterogeneous porous media with a capillary pressure, between an injection well and a production well.

According to another embodiment, there is a computing device for implementing a physics-preserving implicit pressure explicit saturation method for simulation of incompressible and immiscible two-phase flow in heterogeneous porous media with capillary pressure. The computing device includes an input/output interface for receiving input data that characterizes a given domain in a subsurface of the earth, and a processor connected to the input/output interface. The processor is configured to select initial parameters K associated with a mixed finite element algorithm, modify Darcy flows to include a total velocity uₜ and a capillarity potential gradient ξ_{c}, establish a total conservation equation by summing a discretized conservation equation for each phase α of the two-phase flow, and calculate at least one parameter based on the modified Darcy flows and the total conservation equation. The at least one parameter characterizes the two-phase flow in the heterogeneous porous media with a capillary pressure, between an injection well and a production well.

According to still another embodiment, there is a physics-preserving implicit pressure explicit saturation method for simulation of incompressible and immiscible two-phase flow in heterogeneous porous media with capillary pressure. The method includes receiving input data that characterizes a given domain in a subsurface of the earth; selecting initial parameters K associated with a mixed finite element algorithm; modifying Darcy flows to include a total velocity uₜ and a capillarity potential gradient ξ_{c}; establishing a total conservation equation by summing a discretized conservation equation for each phase a of the two-phase flow; and calculating at least one parameter based on the modified Darcy flows and the total conservation equation.

### BRIEF DESCRIPTION OF THE DRAWINGS

For a more complete understanding of the present invention, reference is now made to the following descriptions taken in conjunction with the accompanying drawings, in which:

FIG. 1 is a flowchart of a method for calculating a fluid flow in a porous media using a traditional model;

FIG. 2 is a flowchart of a method for calculating parameters of a flow in a subsurface using a physics-preserving scheme for the simulation of incompressible and immiscible two-phase flow in heterogeneous porous media with capillary pressure;

FIG. 3 illustrates the distribution of the permeability of the porous media in logarithmic value;

FIGS. 4A to 4D illustrate the saturation of the wetting phase in a drainage process calculated according to the physics-preserving scheme;

FIG. 5A illustrates the spatial average of the wetting phase saturation for a given domain and FIG. 5B illustrates the spatial average of the non-wetting phase saturation;

FIG. 6A illustrates the initial water and oil distribution used to simulate the flow with novel method, and FIG. 6B illustrates the permeability of the same in the logarithmic scale;

FIGS. 7A to 7D illustrate, for another example, the saturation of the wetting phase in a drainage process calculated according to the physics-preserving scheme;

FIG. 8 illustrates the spatial average of the phase separations for the example illustrated in FIGS. 7A to 7D;

FIG. 9 illustrates the phase saturations for a fluid flow calculated based on a conventional method;

FIG. 10 illustrates the spatial average saturations of the phases calculated with the conventional method;

FIG. 11 is a schematic diagram of a computing device that implements the methods discussed above; and

FIG. 12 is a flowchart of a physics-preserving, implicit pressure, explicit saturation method for simulation of incompressible and immiscible two-phase flow in heterogeneous porous media with capillary pressure.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to an oil and gas subsurface reservoir having an injection well, through which water is injected, and a production well, through which oil is extracted. However, the embodiments to be discussed next are not limited to an oil and gas reservoir, but may be applied to any type of fluids with or without the presence of a well.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, the IMPES and HF-IMPES schemes are modified so that the Darcy flows for both phases are rewritten based on the total velocity and an auxiliary velocity, which is referred to herein as the capillary potential gradient. An upwind scheme is used in the spatial discretization for the conservation equation of each phase, and then the total conservation equation is obtained by summing the discretized conservation equations of each phase. Using the unknowns for the total velocity, the auxiliary velocity and the pressures of both phases, the new scheme applies the mixed finite element method to the upwind scheme to solve the pressure-velocity system. When the wetting saturation is given, the coupled pressure-velocity system can be decoupled into two decoupled systems which are well-posed, and then the saturations of both phases can be explicitly updated. The new IMPES scheme is unbiased with regard to the two phases of the flow.

Moreover, the proposed scheme is conditionally bounds-preserving, which means that the computed saturation of each phase always sits within its physical bounds if the time step size is smaller than a certain value.

Before discussing the new IMPES scheme, the traditional mathematical model for incompressible and immiscible two-phase flow in porous media is discussed. Let the wetting phase and the non-wetting phase be denoted by the subscripts wand n, respectively. Based on (i) the mass conservation law, see equation (1.1), (ii) Darcy's law, see equation (1.2), (iii) the saturations constraint, see equation (1.3), and (iv) the capillary pressure, see equation (1.4), the two-phase flow with gravity in a porous media Ω⊂ [symbol] ^{d} (with d=2,3) is described by:

$$\begin{matrix}ϕ \frac{\partial {S}_{α}}{\partial t} + ∇ \cdot {u}_{α} = {F}_{α} , in Ω , α = w , n , & ( 1.1 ) \\ {u}_{α} = - \frac{{k}_{r α}}{{μ}_{α}} K ( ∇ \cdot {p}_{α} - {ρ}_{α} g ∇ \cdot z ) , in Ω , α = w , n , & ( 1.2 ) \\ {S}_{n} + {S}_{w} = 1 , in Ω , & ( 1.3 ) \\ {p}_{c} ( {S}_{w} ) = {p}_{n} - {p}_{w ,} in Ω , & ( 1.4 )\end{matrix}$$

where ϕ is the porosity of the medium, K denotes the absolute permeability tensor, Sₐ is the saturation of each phase α, u_{α} is the Darcy's velocity of each phase, p_{α} is the pressure of each phase, F_{α} is the sink/source term of each phase, and p_{c} is the capillarity pressure.

In equation (1.2), ρ_{α} is the density of phase α, k_{rα} is the permeability of each phase, μ_{α} is the viscosity of each phase, g is the magnitude of the gravitational acceleration, and z is the depth relative to the surface where the flow takes place. The phase mobility λ_{α} is defined by

$${λ}_{α} = \frac{{k}_{r α}}{{μ}_{α}} ,$$

and the total mobility is given by λₜ=λ_{w}+λₙ. The fractional flow functions are defined as ƒ_{w}=λ_{w}/λₜ and fₙ=λₙ/λₜ.

The boundary of the porous media Ω is defined by Γ=∂Ω, which has two terms, Γ_{D} and Γ_{N}, where Γ_{D} is the Dirichlet part of the boundary, and Γ_{N} is the Neumann part of the boundary. These two parts Γ_{D} and Γ_{N} of the boundary satisfy the following conditions: Γ=Γ_{D}∪Γ_{N} and Γ_{D}∩Γ_{N}=0. In addition, the boundary can also be written as Γ=Tᵢₙ∪Γₒᵤₜ, where Γᵢₙ={x∈Γ: uₜ(x)·n(x)<0} is the inflow boundary and Γₒᵤₜ={x∈Γ: uₜ(x)·n(x)≥0} is the outflow boundary, uₜ=uₙ+u_{w} is the total velocity, and n is the unit outward normal to boundary r.

The initial and boundary conditions are imposed to the equations (1.1) to (1.4) as follows:

$$\begin{matrix}{S}_{α} = {S}_{α}^{0} , t = 0 , & ( 2.1 ) \\ {p}_{α} = {p}_{α}^{B} , on {Γ}_{D} , α = w , n , & ( 2.2 ) \\ {u}_{α} n = {g}_{α}^{N} , on {Γ}_{N} , α = w , n , & ( 2.3 ) \\ {S}_{α} = {S}_{α}^{B} , on {Γ}_{i n} , α = w , n & ( 2.4 )\end{matrix}$$

where N indicates the normal and B indicates the boundary (i.e., the Dirichlet or Neumann boundary).

The scheme assumes that the absolute permeability tensor K is heterogenous and symmetric positive and definite, the porosity ϕ is time-independent and uniformly bounded below and above, and there exists positive constants λ̅_{w}, λ̅ₙ and λ̅ₜ such that the mobilities satisfy 0≤λ_{w}(S_{w})≤λ̅_{w}, 0≤λₙ(S_{w})≤λ̅ₙ, 0≤λₜ(S_{w})≤λ̅ₜ.

In the homogeneous porous media, the saturations are continuous and the standard IMPES scheme [20, 21] has been widely used to simulate the two-phase flow. In the heterogenous porous media, the capillarity discontinuity may often arise from contrast in capillarity pressure functions, and the saturation is discontinuous due to the continuity of the capillarity pressure and the change of the capillarity function across the space. The HF-IMPES scheme accounts for the different capillarity pressure functions. For this improved scheme, the following notations are introduced: the flow potential of phase α is given by Φ_{α}=p_{α}+ρ_{α}gz with α=w,n and the capillarity potential Φ_{c}=Φₙ−Φₘ=p_{c}+(ρₙ−ρ_{w})gz. The total velocity uₜ can be defined as a function of two velocity variables as uₜ=u_{α}+u_{c}, where u_{α}=−λₜK∇Φₘ and u_{c}=−λₙK∇Φₘ.

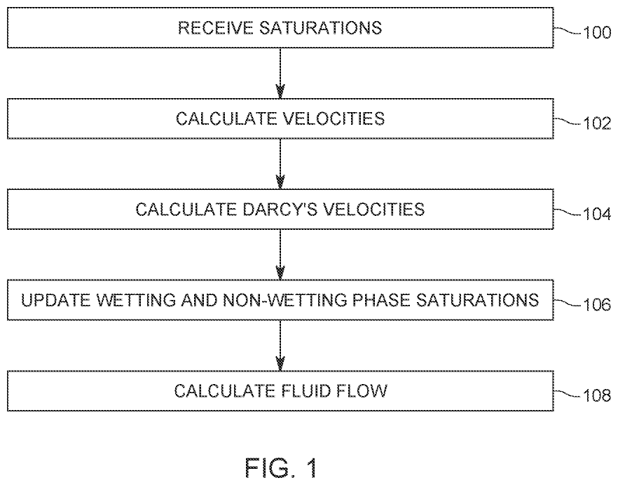

The HF-IMPES scheme follows the steps discussed with regard to FIG. 1. In step 100, the method receives the S_{w}ⁿ. In step 102, the method calculates u_{c}ⁿ⁺¹ such that u_{c}ⁿ⁺¹=−λₙ(S_{w}ⁿ)K∇Φ_{c}(S_{w}ⁿ). In step 104, having S_{w}ⁿ and u_{c}ⁿ⁺¹, the u_{c}ⁿ⁺¹ and Φ_{w}ⁿ⁺¹ are calculated by using equations: ∇uₐⁿ⁺¹=Fₜ−∇u_{c}ⁿ⁺¹, and uₐⁿ⁺¹=−λₜ(S_{w}ⁿ)K∇Φ_{w}ⁿ⁺¹. In step 106, the method explicitly updates the wetting and non-wetting phase saturations, based on S_{w}ⁿ, uₐⁿ⁺¹, and Φ_{w}ⁿ⁺¹, and equations:

$$ϕ \frac{{S}_{w}^{n + 1} - {S}_{w}^{n}}{{t}_{n + 1} - {t}_{n}} = {F}_{w} - ∇ \cdot ( {f}_{w} ( {S}_{w}^{n} ) {u}_{a}^{n + 1} ) ,$$

and S_{w}ⁿ⁺¹=1−S_{w}ⁿ⁺¹. Based on the wetting and non-wetting phase saturations, the method then calculates the fluid flow through the subsurface in step 108.

It is noted that the HF-IMPES scheme is locally mass-conservative only for the wetting phase, but not for the non-wetting phase, just like the standard IMPES scheme. In addition, both the standard IMPES and HF-IMPES schemes are biased with regard to the two phases (i.e., they threat differently the wetting phase from the non-wetting phase) and might produce a wetting-phase saturation that is larger than one. To overcome such disadvantages, a novel scheme is now introduced, which is a physics-preserving scheme, and solves the two-phase flow problem characterized by equations (1.1) to (2.4) in heterogeneous porous media.

The novel physics-preserving IMPES schemes is called herein P-IMPES and it uses the standard notations and definitions for the Sobolef spaces [1], For any D⊂Ω̅, the inner products for any scalar functions ψ and ϕ, and vectors functions ψ and ϕ are defined as:

(ψ,ϕ)_{D}=∫_{D}ψϕdx and (ψ,ϕ)_{D}=ψϕdx. (3)

When D=Ω, the following notation ∥⋅∥_{0,D} is used to indicate the L²-norm on D. A quasi-uniform grid on the domain Ω is denoted by [symbol] . The set of all faces (d=3) or edges (d=2) of the grid [symbol] is εₕ, and h_{K} is the diameter of any element K∈ [symbol] , where h= [symbol] h_{K}. The domain Ω may be a triangle or quadrilateral for 2D domains, and tetrahedrons, prisms, or hexahedrons for 3D, and a mesh cell is K. For K,K′∈ [symbol] , it is assumed that F=∂K∩∂K′ with the outward unit normal vector u_{F} exterior to K. Further, it is denoted by [symbol] ψ [symbol] =(ψ_{K})_{F}−(ψ|_{K′})|_{F} the jump of scalar function ψ across interior edges/faces F, and by [ψ]=½(ψ_{K}|)_{F}+(ψ|_{K′})|_{F}) the average of scalar function ψ across interior edges/faces F. For edges/faces on ∂Ω, [symbol] ψ [symbol] and {ψ} denote ψ. Further, the symbol C is used, with or without subscript, to indicate a positive constant, depending on the shape regularity of the meshes and the coefficients data in equations (1.1) to (1.4).

Next, the mixed finite element spaces are introduced, which will be used for the special discrete schemes. On the simplicial mesh [symbol] , the lowest-order of Raviart-Thomas finite element space is considered to be:

RT₀( [symbol] )={v∈L^{d}(Ω):∀K∈ [symbol] ,v=a+bx,a∈R^{d},b∈R,x∈K, [symbol] v [symbol] =0 on ∀F∈εₕ†∂Ω}. (4)

The quantity RT₀( [symbol] ) is defined to be Uₕ, Qₕ={qₕ∈L²(Ω)=qₕ|_{K}∈P₀(K), ∀K∈ [symbol] } is the piecewise constant space, and Uₕ⁰={v∈Uₕ:v·n=0 on Γ_{N}} is the mixed finite element space. When the lowest-order Raviart-Thomas mixed finite element method is used for the discretization on the structured grid, the mixed finite element method based on the trapezoidal rule for integration is equivalent to the cell-centered finite difference method on structured grid.

Next, the P-IMES scheme is discussed in more detail. First, define ξ_{α}=λₜw_{α} with w_{α}=−K(∇p_{α}+ρ_{α}g∇z), where α=n,w. Then, the speed for each phase is given by u_{α}=ƒ_{α}ξ_{α}, where ƒ_{α} is the fractional flow function. The total velocity is given by uₜ=uₙ+u_{w} and ξ_{c}=ξₙ−ξₘ. With these definitions, the speed for each phase can be written as:

u_{w}=ƒ_{w}uₜ−ƒ_{w}ƒₙξ_{c}, (5-1)

uₙ=ƒₙuₜ−ƒ_{w}ƒₙξ_{c}, (5-2)

It is assumed that uₜ,ξ_{c}∈H(div,Ω), p_{α}∈L²(Ω), and S_{α}∈L²(Ω).

The two-phase flow problem described by equations (1.1 to 2.4) can now be rewritten, with the above notations, in the following weak formulation, which separates the two phases n and w. For any v∈H(div,Ω) and q∈L²(Ω), find a total velocity vₜ∈H(div,Ω), ξ_{c}∈H(div,Ω), pressure p_{α}∈L²(Ω), and saturation S_{α}∈L²(Ω), for both phases α=n,w, such that the following equations are satisfied:

$$\begin{matrix} ( ϕ \frac{\partial {S}_{w}}{\partial t} , q ) + ( ∇ \cdot ( {f}_{w} {u}_{t} ) , q ) = ( {F}_{w} , q ) + ( ∇ \cdot ( {f}_{n} {f}_{w} {ζ}_{c} ) ) , & ( 6.1 a ) \\ ( ϕ \frac{\partial {S}_{n}}{\partial t} , q ) + ( ∇ \cdot ( {f}_{n} {u}_{t} ) , q ) = ( {F}_{n} , q ) - ( ∇ \cdot ( {f}_{n} {f}_{w} {ζ}_{c} ) ) , & ( 6.1 b ) \\ ( {( {λ}_{t} K )}^{- 1} {u}_{t} , v ) = ( {( {λ}_{t} K )}^{- 1} {f}_{n} {ξ}_{c} , v ) + ( {p}_{w} , ∇ \cdot v ) - {\int }_{{Γ}_{D}} {p}_{w}^{B} v \cdot n - ( {ρ}_{w} g ∇ \cdot z , v ) , & ( 6.2 a ) \\ ( {( {λ}_{t} K )}^{- 1} {u}_{t} , v ) = - ( {( {λ}_{t} K )}^{- 1} {f}_{w} {ξ}_{c} , v ) + ( {p}_{n} , ∇ \cdot v ) - {\int }_{{Γ}_{D}} {p}_{n}^{B} v \cdot n - ( {ρ}_{n} g ∇ \cdot z , v ) , & ( 6.2 b ) \\ {S}_{n} + {S}_{w} = 1 , & ( 6.3 ) \\ ( {p}_{c} - {p}_{w} , q ) = ( {p}_{c} ( {S}_{w} ) , q ) & ( 6.4 a )\end{matrix}$$

It is noted that the Darcy flows for both phases in equations (6.2a and 6.2b) are rewritten in the formulation based on the total velocity uₜ and an auxiliary velocity ξ_{c}, which is referred to as the capillary potential gradient. Next, the new physics-preserving IMPES scheme is introduced for the two-phase flow problem described by equations (1.1 to 2.4), based on the above system of equations (6.1a to 6.4b). For any velocity v∈Uₕ, q∈Qₕ, and S_{w}^{h}∈Qₕ, in a discrete space defined by h, the following bilinear notation is introduced:

$${B}_{α} ( v , q ; {S}_{w}^{h} ) = ( ∇ \cdot ( {f}_{α} ( {S}_{w}^{h} ) v ) , q ) - {\sum }_{K ∈ {𝒯}_{h}} {\int }_{\partial {K}_{\overline{α}} \backslash Γ} {f}_{α} ( {S}_{w}^{h} ) v \cdot nq , \qquad ( 7 )$$

where ∂K_{α̅}={e⊂∂K:{u_{α}^{h}·nₑ}|ₑ<0} with the normal vector nₑ exterior to K. Here, u_{α}^{h} is the discrete velocity of phase α for a given h. Note the sum symbol in equation (7), which adds all the discrete components. In fact, equation (7) is part of an upwind scheme (i.e., a class of numerical discretization methods for solving hyperbolic partial differential equations) for ƒ_{α}(S_{w}^{h}) on ∂K. This is so because, if q∈Qₕ is the piecewise constant, it is possible to compute the term B_{α}(v, q; S_{w}^{h}) as follows:

$${B}_{α} ( v , q ; {S}_{w}^{h} ) = {\sum }_{K ∈ {𝒯}_{h}} {\int }_{\partial K} {f}_{α} ( {S}_{w}^{h} ) v \cdot nq - {\sum }_{K ∈ {𝒯}_{h}} {\int }_{\partial {K}_{\overline{α}} \backslash Γ} {f}_{α} ( {S}_{w}^{h} ) v \cdot nq = {\sum }_{K ∈ {𝒯}_{h}} {\int }_{\partial K} {f}_{α} ( {S}_{w , α}^{* , h} ) v \cdot nq , \qquad ( 8 )$$

where the upwind value S_{w,α}^{*,h} in the function ƒ_{α}(S_{w,α}^{*,h}) is defined as follows:

$${S}_{α}^{* , h} = \{ \begin{matrix}{{S}_{α}^{h} \vert}_{{K}_{i}} , if {\{ {u}_{α}^{h} \cdot {n}_{γ} \}}_{γ} \geq 0 , \\ {{S}_{α}^{h} \vert}_{{K}_{j}} , if {\{ {u}_{α}^{h} \cdot {n}_{γ} \}}_{γ} < 0 ,\end{matrix} and \\ {S}_{w , α}^{* , h} = \{ \begin{matrix}{S}_{w}^{* h} , α = w , \\ 1 - {S}_{n}^{* , h} , α = n .\end{matrix} and$$

Here, γ is given by γ=∂Kᵢ∩∂Kⱼ, with the normal vector n_{γ} exterior to Kᵢ. If γ⊂Γ_{D}, then S_{w,α}^{*,h}|γ=P_{γ}S_{w}^{B}|_{γ}, where P_{γ} is the L² projection operator into P₀(γ).

An additional term B_{c}(v, q; S_{w}^{h}) is defined as follows:

$${B}_{c} ( v , q ; {S}_{w}^{h} ) = ( ∇ \cdot ( {f}_{n} ( {S}_{w}^{h} ) {f}_{w} ( {S}_{w}^{h} ) {ξ}_{c} ) , q ) - {\sum }_{K ∈ {𝒯}_{h}} {\int }_{\partial {K}_{\overline{w}} ⋂ {K}_{\overline{n}} \backslash Γ} {f}_{n} ( {S}_{w}^{h} ) {f}_{w} ( {S}_{w}^{h} ) v \cdot nq - {\sum }_{K ∈ {𝒯}_{h}} {\int }_{\partial {K}_{\overline{w}} \backslash {K}_{\overline{n}} ⋃ Γ} {f}_{w} ( {S}_{w}^{h} ) {f}_{n} ( {S}_{w , n}^{* , h} ) v \cdot nq - {\sum }_{K ∈ {𝒯}_{h}} {\int }_{\partial {K}_{\overline{n}} \backslash {K}_{\overline{w}} ⋃ Γ} {f}_{n} ( {S}_{w}^{h} ) {f}_{n} ( {S}_{w , w}^{* , h} ) v \cdot nq . \qquad ( 9 )$$

For any q∈Qₕ, equation (9) becomes:

$${B}_{c} ( v , q ; {S}_{w}^{h} ) = {\sum }_{K ∈ {𝒯}_{h}} {\int }_{\partial K} {f}_{n} ( {S}_{w , n}^{* , h} ) {f}_{w} ( {S}_{w , w}^{* , h} ) v \cdot nq . \qquad ( 10 )$$

For a time interval J=(0,T], the following continuous-in-time and discrete-in-space nonlinear system needs to be solved for the two-phase flow problem defined by equations (1.1 to 2.4) in porous media. Denoting σ_{w}=1 and σₙ=−1, for any v∈Uₕ⁰ and q∈Qₕ, the aim is to find uₜ^{h}(⋅,t)∈Uₕ, ξ_{c}^{h}(⋅,t)∈Uₕ, p_{α}^{h}(⋅,t)∈Qₕ, S_{α}^{h}(⋅,t)∈Qₕ, α=w,n, based on the following equations, which includes equations (9) and (10),

$$\begin{matrix}( ϕ \frac{\partial {S}_{α}^{h}}{\partial t} , q ) + {B}_{α} ( {u}_{t}^{h} , q ; {S}_{w}^{h} ) = ( {F}_{w} , q ) + {σ}_{α} {B}_{c} ( {ξ}_{c}^{h} , q ; {S}_{w}^{h} ) , α = w , n , t ∈ J & ( 11.1 ) \\ ( {( {λ}_{t} K )}^{- 1} {u}_{t}^{h} , v ) - ( {p}_{w}^{h} , ∇ \cdot v ) = ( {( {λ}_{t} K )}^{- 1} {f}_{n} {ξ}_{c}^{h} , v ) - {\int }_{{Γ}_{D}} {p}_{n}^{B} v \cdot n - ( {ρ}_{w} g ∇ \cdot z , v ) , t ∈ J & ( 11.2 a ) \\ ( {( {λ}_{t} K )}^{- 1} {u}_{t}^{h} , v ) - ( {p}_{w}^{h} , ∇ \cdot v ) = - ( {( {λ}_{t} K )}^{- 1} {f}_{w} {ξ}_{c}^{h} , v ) - {\int }_{{Γ}_{D}} {p}_{n}^{B} v \cdot n - ( {ρ}_{n} g ∇ \cdot z , v ) , t ∈ J & ( 11.2 b ) \\ {S}_{n}^{h} + {S}_{w}^{h} = 1 , t ∈ J & ( 11.3 ) \\ ( {p}_{n}^{h} - {p}_{w}^{h} , q ) = ( {p}_{c} ( {S}_{w}^{h} ) , q ) t ∈ J & ( 11.4 a ) \\ ( {S}_{w}^{h} , q ) = ( {S}_{w}^{0} , q ) , t = 0. & ( 11.4 b )\end{matrix}$$

It is noted that the above system of equations (11.1) to (11.4b) is nonlinear and well-posed. Thus, this system can be solved by considering that S_{w}^{h,n}∈Qₕ is given at the time step n of the algorithm. Then, the following quantities can be calculated, for the next step n+1, based on the system of equations (11.1) to (11.4b). These quantities are: uₜ^{h,n+1}∈Uₕ, ξ_{c}^{h,n+1}∈Uₕ, p_{α}^{h,n+1}∈Qₕ, S_{α}^{h,n+1}∈Qₕ, α=w,n and they can be calculated as follows:

$$\begin{matrix}( ϕ \frac{{S}_{α}^{h , n + 1} - {S}_{α}^{h , n}}{{t}_{n + 1} - {t}_{n}} , q ) + {B}_{α} ( {u}_{t}^{h , n + 1} , q ; {S}_{w}^{h , n} ) = ( {F}_{w} , q ) + {σ}_{α} {B}_{c} ( {ξ}_{c}^{h , n + 1} , q ; {S}_{w}^{h , n} ) , α = w , n , t ∈ J & ( 12.1 ) \\ ( {( {λ}_{t} K )}^{- 1} {u}_{t}^{h , n + 1} , v ) - ( {p}_{w}^{h , n + 1} , ∇ \cdot v ) = ( {( {λ}_{t} K )}^{- 1} {f}_{n} {S}_{w}^{h , n} {ξ}_{c}^{h , n + 1} , v ) - {\int }_{{Γ}_{D}} {p}_{w}^{B} v \cdot n - ( {ρ}_{w} g ∇ \cdot z , v ) , t ∈ J & ( 12.2 a ) \\ ( {( {λ}_{t} K )}^{- 1} {u}_{t}^{h , n + 1} , v ) - ( {p}_{n}^{h , n + 1} , ∇ \cdot v ) = - ( {( {λ}_{t} K )}^{- 1} {f}_{w} {S}_{w}^{h , n} {ξ}_{c}^{h , n + 1} , v ) - {\int }_{{Γ}_{D}} {p}_{n}^{B} v \cdot n - ( {ρ}_{n} g ∇ \cdot z , v ) , t ∈ J & ( 12.2 b ) \\ {S}_{n}^{h , n + 1} + {S}_{w}^{h , n + 1} = 1 , t ∈ J & ( 12.3 ) \\ ( {p}_{n}^{h , n + 1} - {p}_{w}^{h , n + 1} , q ) = ( {p}_{c} ( {S}_{w}^{h} ) , q ) & ( 12.4 )\end{matrix}$$

By summing the above discrete conservation law (equation (12.1) for each phase and noting the constraint of the saturations of phases imposed by equation (12.3), and the fact that the sum of the discrete terms Σ_{α}σₐB_{c}(ξ_{c}^{h,n+1}, q; S_{w}^{h,n})=0. the following linear system needs to be solved to obtain the desired quantities uₜ^{h,n+1}∈Uₕ, ξ_{c}^{h,n+1}∈Uₕ, p_{α}^{h,n+1}∈Qₕ, α=w,n:

$$\begin{matrix} {\sum }_{α} {B}_{α} ( {u}_{t}^{h , n + 1} , q ; {S}_{w}^{h , n} ) = ( {F}_{w} , q ) & ( 13.1 ) \\ ( {( {λ}_{t} K )}^{- 1} {u}_{t}^{h , n + 1} , v ) - ( {p}_{w}^{h , n + 1} , ∇ \cdot v ) = ( {( {λ}_{t} K )}^{- 1} {f}_{n} ( {S}_{w}^{h , n} ) {ξ}_{c}^{h , n + 1} , v ) - {\int }_{{Γ}_{D}} {p}_{w}^{B} v \cdot n - ( {ρ}_{w} g ∇ \cdot z , v ) , & ( 13.2 a ) \\ ( {( {λ}_{t} K )}^{- 1} {u}_{t}^{h , n + 1} , v ) - ( {p}_{n}^{h , n + 1} , ∇ \cdot v ) = - ( {( {λ}_{t} K )}^{- 1} {f}_{w} ( {S}_{w}^{h , n} ) {ξ}_{c}^{h , n + 1} , v ) - {\int }_{{Γ}_{D}} {p}_{n}^{B} v \cdot n - ( {ρ}_{n} g ∇ \cdot z , v ) , & ( 13.2 b ) \\ ( {p}_{n}^{h , n + 1} - {p}_{w}^{h , n + 1} , q ) = ( {p}_{c} ( {S}_{w}^{h} ) , q ) & ( 13.3 )\end{matrix}$$

Note that if ƒₙ(S_{w}^{h,n})+ƒ_{w}(S_{w}^{h,n})=1 and ∇·v∈Qₕ, then using equations (13.2a), (13.2b), and (13.3), the following equation is obtained:

((λₜK)⁻¹ξ_{c}^{h,n+1},v)=(p_{c}(S_{w}^{h,n}),∇·v)−∫_{Γ}_{_{D}}(pₙ^{B}−p_{w}^{B})v·n−((ρₙ−ρ_{w})g∇·z,v). (13.4)

Equation (13.4) is well-posed for the solution of ξ_{c}^{h,n+1}. Thus, the solution of the linear system described by equations (13.1) to (13.3) can be decoupled in two steps, as now discussed. First, equation (13.3) can be solved to obtain pₙ^{h,n+1}−p_{w}^{h,n+1}, then solve equation (13.4) to obtain ξ_{c}^{h,n+1}. Next, the terms p_{w}^{h,n+1} and uₜ^{h,n+1} can be obtained from equations (13.1) and (13.2a), after which the term pₙ^{h,n+1} can be obtained. Second, it is possible to update the wetting phase saturation S_{w}^{h,n+1} using equation (12.1) with α=w and directly obtain the non-wetting phase saturation by using equation (12.3). Because the method directly solves the total velocity by mixed finite element method, the total velocity is continuous in its normal direction in this method.

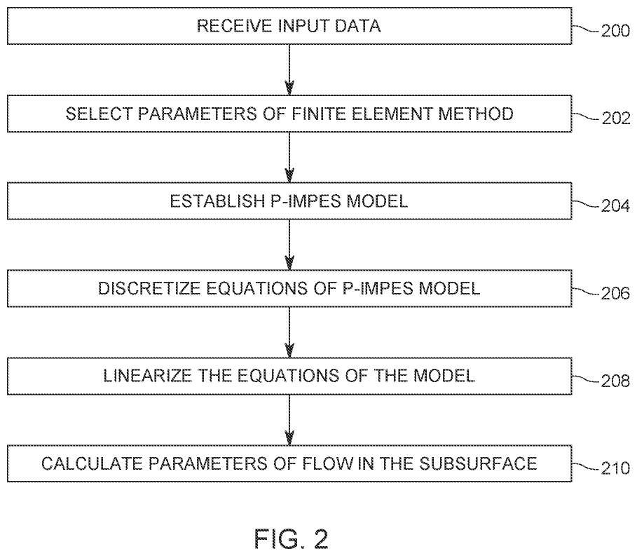

The novel P-IMPES method is now discussed with regard to FIG. 2. In step 200, input data about the two-phase flow of a fluid through a given volume in the subsurface is provided. The input data, at a minimum, may include the saturation of the subsurface, the porosity of the subsurface, the relative permeability of the subsurface. Other data, as the residual saturations, the density of the wetting and non-wetting phases, the viscosity of these two phases, the depth where the flow is calculated, may be received. This data may be obtained from previous measurements taken from one or more wells that enter the subsurface, or from various predictive models that use seismic data and inversion algorithms to estimate these parameters.

In step 202, various parameters of the finite element method are selected, as for example, the size of the domain size, and the number of elements of the mesh. In step 204, the P-IMPES model is established. The P-IMPES model includes plural conditions: a mass conservation law for each of the wetting and non-wetting phases (see equations (6.1a) and (6.1b)), modified Darcy's flows for each phase (see equations (6.2a) and (6.2b)), a saturation constraint (see equation (6.3)), and the capillarity pressure (see equation (6.4a)). Note that the plural conditions are implemented in a computing device (discussed later) for specifically calculating the flow of oil in the subsurface.

In one application, the modified Darcy's flows are expressed based on a total velocity of the fluid that flows in the subsurface and an auxiliary velocity, which is also called the capillarity potential gradient. The capillarity potential gradient is expressed as a product of the total mobility and a part of Darcy's law (see equation (1.2).

In step 206, the modified Darcy's flows are discretized (see, equation (11.1)) based on the mixed finite element spaces, using, for example, the Raviart-Thomas finite element space. In step 208, the above noted plural conditions are linearized (see equations (12.1) to (12.4)) and then solved in step 210 (based on equations (13.1) to (13.4)) to find the phase velocities and pressures of each phase, and the saturations and permeabilities of the phases.

The P-IMPES scheme discussed above may be formulated in the matrix-vector space, which is useful for implementation in a computing device for practical applications. More specifically, for any shape-regular structured/unstructured mesh [symbol] , N is considered to be the number of edges (2D) or faces (3D) and M is the number of elements in the mesh [symbol] . Because Qₕ is the piecewise constant space, for the basis function qⱼ∈Qₕ, it is possible to use qⱼ|_{K}=1 and qⱼ|_{Ω†K}=0 for any K∈ [symbol] . For the basis functions ϕᵢ∈RT₀( [symbol] ), it is possible to obtain their detailed construction on the 2D unstructured mesh (see, for example, [5] and [6]) for simplicity. Let Fᵢ, i=1, 2, 3 be the edges of any triangular K∈ [symbol] opposite to the vertices Pᵢ, i=1, 2, 3, and let nᵢ denote the outer unit normal on K along Fᵢ and nᵢ^{F} be the unit normal vector on the edge Fᵢ with a global fixed orientation. Then, the local basis function ϕᵢ on the element K can be defined as:

$${ϕ}_{i} = {σ}_{i} \frac{\vert {F}_{i} \vert}{2 \vert K \vert} ( x - {P}_{i} ) , \qquad ( 14 )$$

where σᵢ=1 if nᵢ^{F} points outward of K and otherwise σᵢ=−1, |Fᵢ| is the length of Fᵢ, and |K| is the area of K.

Based on the construction of the basis functions for RT₀CFₕ) and Qₕ, the following vectors and matrices are introduced:

Aₕ=(∫_{Ω}(λₜK)⁻ϕᵢ−ϕⱼ)_{i,j=1, . . . ,N}∈ [symbol] ^{N×N}, and (15.1)

Bₕ=(∫_{Ω}qⱼ∇·ϕᵢ)_{i=1, . . . ,N,j=1, . . . ,M}∈ [symbol] ^{N×M} (15.2).

For any v∈RT₀( [symbol] ), noting that the upwind values ƒₙ(S_{w,n}^{*,h}) and ƒ_{w}(S_{w,w}^{*,h}) are both single value on each edge, then it follows that ƒ_{α}(S_{w,α}^{*,h})v∈RT₀( [symbol] ), for α=n,w, and ƒₙ(S_{w,n}^{*,h})ƒ_{w}(S_{w,w}^{*,h})v∈RT₀( [symbol] ). Further, the following quantities are introduced:

$$\begin{matrix} {B}_{α}^{h} = {( {\int }_{Ω} {q}_{j} ∇ \cdot ( {f}_{α} ( {S}_{w , α}^{* , h} ) {ϕ}_{i} ) )}_{i = 1 , … , N , j = 1 , … , M} ∈ {ℝ}^{N \times M} , and & ( 16.1 ) \\ {B}_{c}^{h} = {( {\int }_{Ω} {q}_{j} ∇ \cdot ( {f}_{n} ( {S}_{w , n}^{* , h} ) {f}_{w} ( {S}_{w , w}^{* , h} ) {ϕ}_{i} ) )}_{i = 1 , … , N , j = 1 , … , M} ∈ {ℝ}^{N \times M} . & ( 16.2 )\end{matrix}$$

The following vectors b_{D}^{h},gₕ, b_{c}^{h}, b_{α,D}^{h}, g_{α}^{h}∈ [symbol] ^{N} and Fₜ^{h}, F_{α}^{h}∈ [symbol] ^{M}, where α=n,w are defined as follow:

b_{D}^{h}=(∫_{Γ}_{_{D}}(pₙ^{h}−p_{w}^{h})ϕᵢ·n)_{i=1, . . . ,N}, (17.1)

gₕ=(∫_{Ω}(ρₙ−ρ_{w})g∇z·ϕi)_{i=1, . . . ,N}, (17.2)

b_{c}^{h}(ξ,S_{w}^{h})=(∫_{Ω}(λₜK)⁻¹ƒₙ(S_{w}^{h})ξ·ϕᵢ)_{i=1, . . . ,N},ξ∈RT₀( [symbol] ),S_{w}^{h}∈ [symbol] ^{M}, (17.3)

b_{α,D}^{h}=(∫_{Γ}_{_{D}}p_{α}^{B}ϕᵢ·Cn)_{i=1, . . . ,N}, (17.4)

g_{α}^{h}=(∫_{Ω}ρ_{α}g∇z·ϕᵢ)_{i=1, . . . ,N}, (17.5)

Fₜ^{h}=(∫_{Ω}Fₜqᵢ)_{i=1, . . . ,M}, (17-6) and

F_{α}^{h}=(∫_{Ω}F_{α}qᵢ)_{i=1, . . . ,M}. (17-7)

With these notations in place, the matrix-vector formulation of the P-IMPES scheme includes a step of calculating the solutions x_{c}^{h,n+1}∈ [symbol] ^{N} of the linear system described by equations (12.1) to (12.4) at the time step n+1, considering that S_{w}^{h,n} ∈ [symbol] ^{M} is given that p_{nw}^{h,n+1}=p_{c}(S_{w}^{h,n})∈ [symbol] ^{M}. Then, using the vectors and matrices introduced by equations (15.1) to (17.7), the systems of equations (12.1) to (12.4) can be rewritten as:

Aₕx_{c}^{h,n+1}=Bₕp_{c}(S_{w}^{h,n})−b_{D}^{h}−gₕ. (17)

Then, ξ_{c}^{h,n+1} can be calculated as ξ_{c}^{h,n+1}=Σᵢ₌₁(x_{c}^{h,n+1})ᵢϕᵢ. Next, the method calculates the total velocity uₜ^{h,n+1}∈ [symbol] ^{N} and the phase pressures p_{w}^{h,n+1}∈ [symbol] ^{M} based on equations:

(Bₙ^{h}+B_{w}^{h})^{T}uₜ^{h,n+1}=Fₜ^{h}, (18.1) and

Aₕuₜ^{h,n+1}−Bₕp_{w}^{h,n+1}=b_{c}^{h}(ξ_{c}^{h,n+1},S_{w}^{h,n})−b_{w,D}^{h}−gw^{h}. (18.2)

Having the total velocity and the phase pressures, the method calculates the non-wetting phase pressure pₙ^{h,n+1}∈ [symbol] ^{M} using the relation pₙ^{h,n+1}=p_{nw}^{h,n+1}+p_{w}^{h,n+1}. Next, the method updates the wetting phase saturation S_{w}^{h,n+1}∈ [symbol] ^{M} and the non-wetting phase saturation Sₙ^{h,n+1}∈ [symbol] ^{M} using equations:

$$\begin{matrix}\frac{ϕ}{δ t} ( {S}_{w}^{h , n + 1} - {S}_{w}^{h , n} ) + {B}_{w}^{h} {u}_{t}^{h , n + 1} = {F}_{w}^{h} + {B}_{c}^{h} {x}_{c}^{h , n + 1} , and & ( 19.1 ) \\ {S}_{n}^{h , n + 1} = 1 - {S}_{w}^{h , n + 1} . & ( 19.2 )\end{matrix}$$

In this implementation, when S_{w}^{h,n} is given, the matrices Bₙ^{h}, B_{w}^{h}, and B_{c}^{h} are generated based on equations S_{w}^{h,n}=Σᵢ₌₁^{M}(S_{w}^{h,n})ᵢqᵢ.

It is also noted that when uₜ^{h,n+1} and x_{c}^{h,n+1} are obtained, the wetting and non-wetting phase velocities can be obtained and then used for the determination of the upwind values of S_{w,n}^{h} and S_{w,w}^{h} on each edge/face at the next time step.

Having discussed the novel P-IMPES method for calculating the velocities, pressures, and saturations of the phases of the two-phase flow of a fluid in a porous media, a number of properties of this scheme are discussed, for example, the fully mass-conservative property, the unbiased property of the solution, and the bounds-preserving property of the saturation for both phases of the fluid.

About the local mass conservation for both phases, the approximate saturations under the P-IMPES scheme satisfy for both phases the discrete mass-conservative law. In this regard, for any K∈ [symbol] , taking q=1 in K̅ and q=0 in Ω†K̅ in equation (12.1), the following local mass-conservation property for both phases is valid:

$${\int }_{K} ϕ \frac{{s}_{α}^{h , n + 1} - {s}_{α}^{h , n}}{{t}_{n + 1} - {t}_{n}} + {\int }_{\partial K} {f}_{α} ( {S}_{w , α}^{* , h , n} ) {u}_{t}^{h , n + 1} \cdot n = {\int }_{K} {F}_{α} + {\int }_{\partial K} {σ}_{α} {f}_{n}^{′} ( {S}_{w , n}^{* , h , n} ) {f}_{w} ( {S}_{w , w}^{* , h , n} ) {ξ}_{c}^{h , n + 1} \cdot n , α = w , n , \qquad ( 20 )$$

where S_{w,α}^{*,h,n} is the upwind value of S_{w,α}^{*,h} on each edge/face of ∂K at the time step n. Note that equation (20) indicates the mass conservation property on the entire volume of the porous media and the boundary of the volume, for any element of the selected mesh.

About the unbiased property of the solution, after obtaining the solutions for the total velocity uₜ^{h,n+1} and the auxiliary velocity ξ_{c}^{h,n+1}, it is possible to update the wetting and non-wetting velocities u_{w}^{h,n+1} and uₙ^{h,n+1} on each element of the selected mesh by using equations (5.1) and (5.2) as follow:

u_{w}^{h,n+1}=ƒ_{w}(S_{w}^{h,n})uₜ^{h,n+1}−ƒ_{w}(S_{w}^{h,n})ƒₙ(S_{w}^{h,n})ξ_{c}^{h,n+1}, (21.1) and

uₙ^{h,n+1}=ƒₙ(S_{w}^{h,n})uₜ^{h,n+1}+ƒ_{w}(S_{w}^{h,n})ƒₙ(S_{w}^{h,n})ξ_{c}^{h,n+1}. (21.2)

It is noted that if equations (13.2a) and (13.4) hold, then equation (13.2b) is obtained. Then, it is also possible to obtain pₙ^{h,n+1} and uₜ^{h,n+1} and then update p_{w}^{h,n+1} by using equation p_{w}^{h,n+1}=pₙ^{h,n+1}−(pₙ^{h,n+1}−p_{w}^{h,n+1}). This indicates that the proposed P-IMPES method is unbiased in the solution of the phase pressures pₙ and p_{w}, i.e., the phase pressures are treated the same way. The same is true for the saturations Sₙ and S_{w}.

Regarding the bounds-preserving property of saturation for both phases, this is true for the P-IMPES scheme when the time step size is smaller than a certain value. For example, let δt=tₙ₊₁−tₙ. For the approximate wetting phase saturation in the P-IMPES scheme, it is assumed that S_{α}^{h,n}∈(0,1) with tolerance saturation S_{tα}, α=w,n. For any K∈ [symbol] , if δt is smaller than a given value, then

S_{α}^{h,n+1}∈(0,1),f or α=w,n. (22)

The given value varies from application to application.

The novel P-IMPES method discussed above is now applied to a couple of examples. The P-IMPES scheme in the matrix-vector formulation is used for these examples. For these examples, it is assumed that the absolute permeability tensor K is chosen as K=KI where I is the identity matrix and K is a positive real number with unit 1 md (millidarcy). In the following experiments, the capillary pressure function is given by [15] as being

$${p}_{c} ( {S}_{w} ) = - \frac{{B}_{c}}{\sqrt{K}} log {\overline{S}}_{w} ,$$

where B_{c} is a positive parameter with unit 1 bar·md^{1/2} and S̅_{w} is the effective saturation defined as in equation (22). These examples further assume that the porosity of the porous media is ϕ=0.2 and the relative permeabilities are given by k_{rw}=S̅_{w}^{β} and kᵣₙ=(1−S̅_{w})^{β}, where β is a positive integer number. In the experiments, the residual saturations are set as S_{rw}=Sₘ=10⁻⁶ and the quadratic relative permeabilities, i.e., β=2 are used.

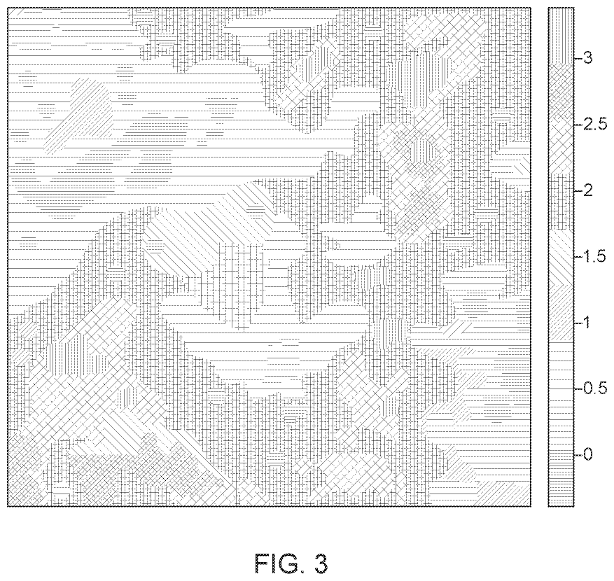

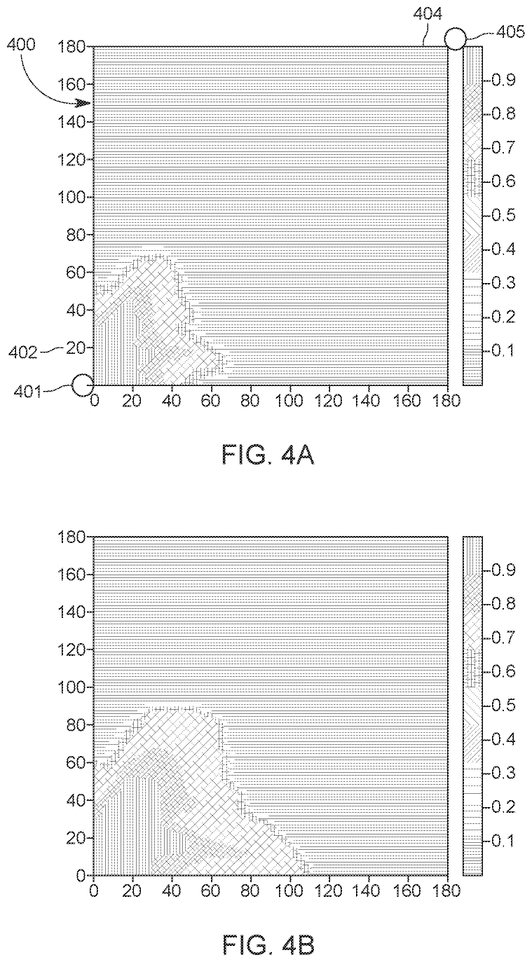

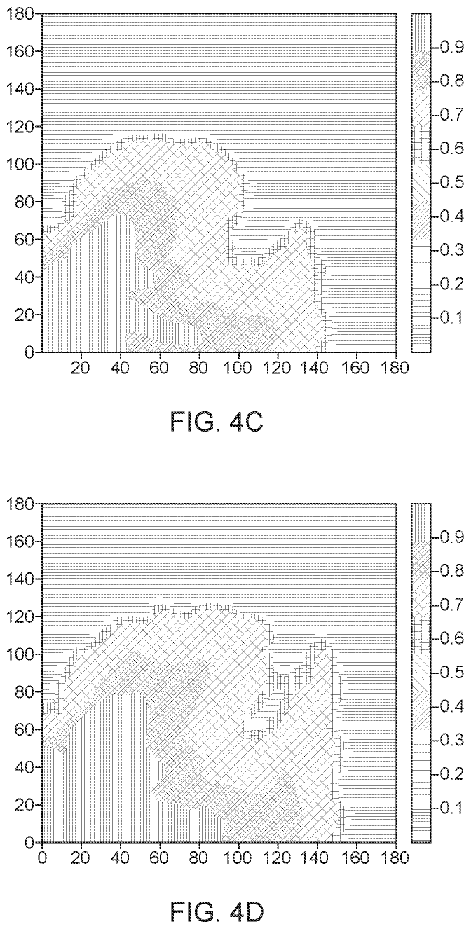

In the first example, a drainage process of the wetting phase is simulated in a heterogeneous porous media with a domain size of 180 m by 180 m. The heterogeneous porous media may be located at a given depth z under the surface, and for this reason it is called the subsurface. The method is applied to a triangular mesh with 7,200 elements. The distribution of the permeability of the porous media in logarithmic value is represented in FIG. 3. The permeability data may be obtained from any known database. In the example of FIG. 3, the permeability data was obtained from the SPE10 data set, which can be downloaded from the SPE website (http://www.spe.org/web/csp/). The method was set up to use the 60 by 60 cutting data (i.e., a horizontal slice from a 3D data volume) of the horizontal permeability in one of the horizontal levels. The density of the wetting phase is set as ρ_{w}=1000 kg/m³ and the density of the non-wetting phase is set as ρₙ=660 kg/m³. The viscosity of the wetting phase is set as μ_{w}=1 cP and the viscosity of the non-wetting phase is set to be ρ_{w}=0.45 cP. The injection of the wetting phase is from an injection well 401 at the bottom-left boundary 402 of one mesh size 400 for the initial state of S_{w}, as shown in FIG. 4A, with a rate of 1.97 m³/day.

It is further assumed that the two-phase flow is extracted at a production well 405, located at the top-right boundary 404 of the one mesh size 400, with a constant pressure of the wetting phase of 100 bar, and the rest of the boundary is impermeable. Furthermore, this example considers that the porous medium is almost fully filled with a non-wetting phase flow (e.g., oil) at the initial state, and uses the parameter B_{c}=1 in the capillary pressure and the time step size as 0:2 day.

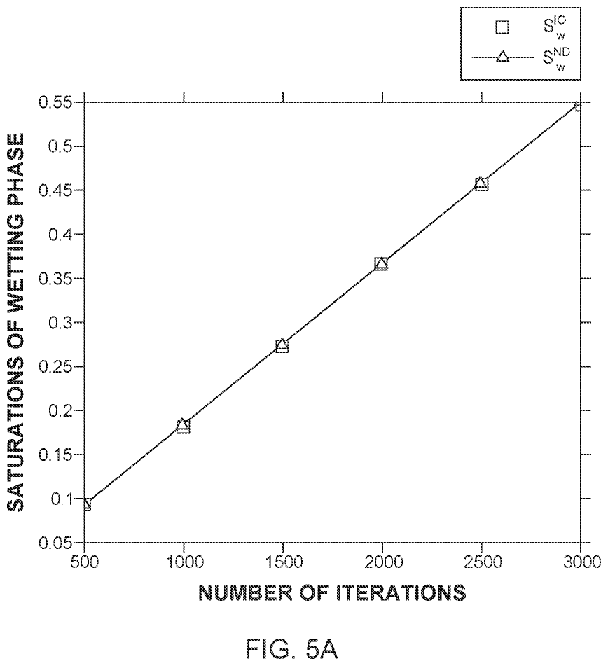

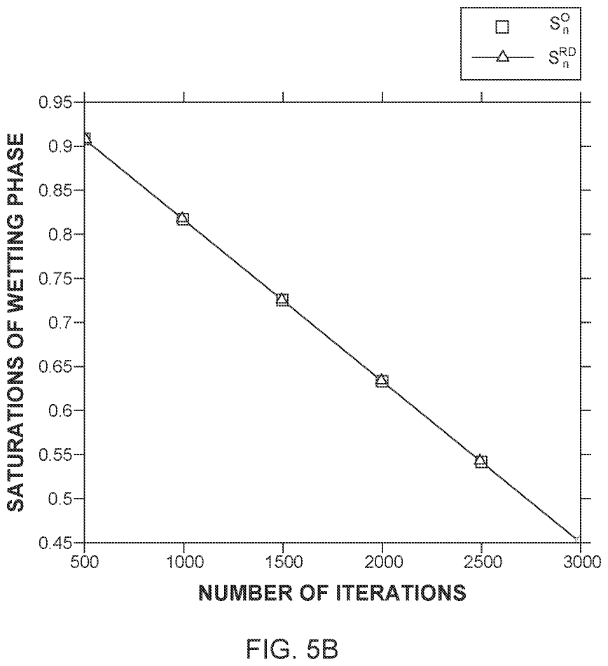

The drainage process at different time steps is illustrated in FIGS. 4A to 4D, which shows the saturations of the wetting phase at time steps 500, 1000, 2,000 and 2,500. The mean saturation of the wetting phase (spatial average of S_{w}) is illustrated in FIG. 5A and is calculated by the injection and the simulation results based on the P-IMPES scheme, and the mean saturation of the non-wetting phase is illustrated in FIG. 5B and also calculated based on the P-IMPES scheme. The mean saturation of the wetting phase in FIG. 5A is denote by S_{w}^{IO}, and it is based on the summation of the injected wetting phase at the new time step and the wetting phase in the porous media at the old time step, and the mean saturation S_{w}^{ND} is based on the summation of the wetting phase in the porous media and the discharge of the wetting phase at the new time step. Similarly, the mean saturation of the non-wetting phase Sₙ^{O} at the old time step and the mean saturation Sₙ^{ND} based on the summation of the residual non-wetting phase in the porous media and the discharge of non-wetting phase at the new time step are illustrated in FIG. 5B. As shown in FIGS. 5A and 5B, the values of S_{w}^{IO} fits well with the values of S_{w}^{ND}, and the values of Sₙ^{O} also fits well with the values of Sₙ^{RD}. These observations indicate the mass conservation property of the P-IMPES method.

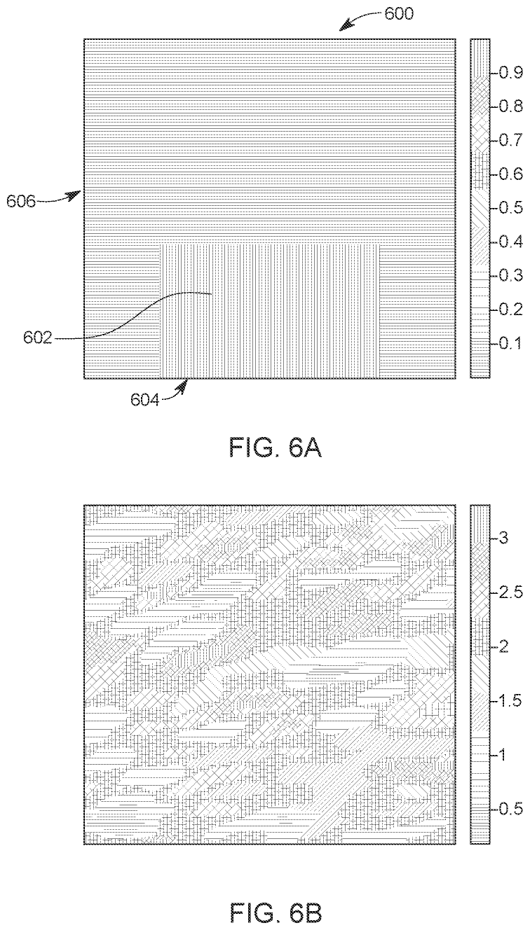

Another example is now discussed with regard to FIGS. 6A to 10. In this example, the algorithm is tested for a two-phase counter flow problem in a heterogeneous porous media with a domain size of 250 m by 250 m. As shown in FIG. 6A, water 602 initially lies in a part of a lower layer 604, which is lighter than the heavy oil 606 that fills out the rest of the domain 600. The domain 600 may be located at a depth z relative to the Earth's surface, in the subsurface. The density of the water 602 is ρ_{w}=1,000 kg/m³ and the density of the heavy oil 606 is ρ_{N}=1,200 kg/m³, and the viscosities of the water (wetting phase) and the heavy oil (non-wetting phase) are set as μ_{w}=1 cP and μ_{N}=0.45 cP, respectively. The gravity g is taken into consideration in this case. The permeability in the logarithmic value is shown in FIG. 6B. The P-IMPES method was tested on a triangular mesh with 5,000 elements and it is assumed that the boundary is impermeable. The parameter in the capillary pressure function was tested for B_{c}=1 and the time step size was set as 1 day in this case.

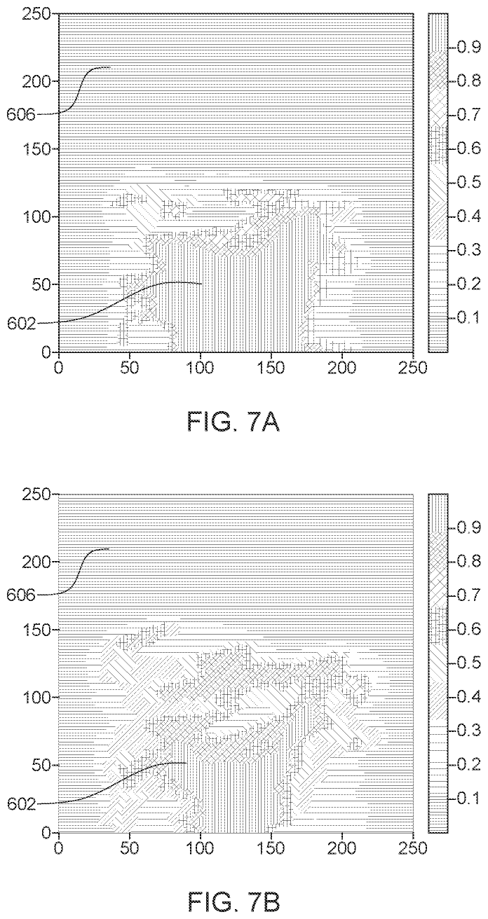

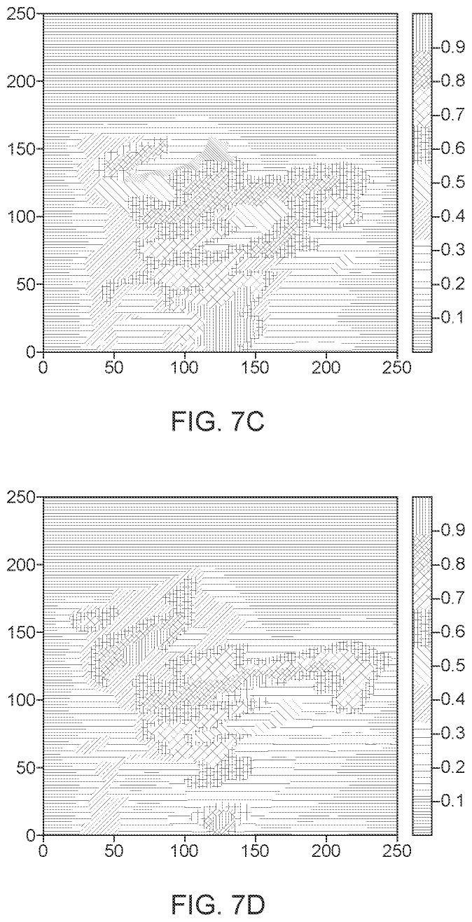

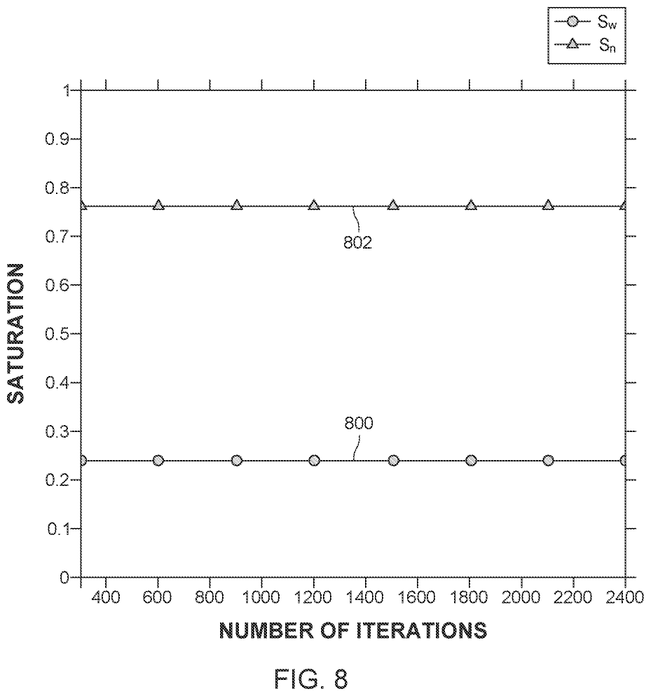

FIGS. 7A to 7D show that the water 602 (the wetting phase) raises up gradually into the oil layer 606, under the effect of the gravity (note that the water is lighter than the oil). The mean saturation of the wetting phase S_{w} is shown as curve 800 in FIG. 8 and the non-wetting phase Sₙ is shown as curve 802 in FIG. 8. The flat profile of these curves over a large number of iterations (on the X axis) indicate that the mass conservation property holds well based on the P-IMPES method.

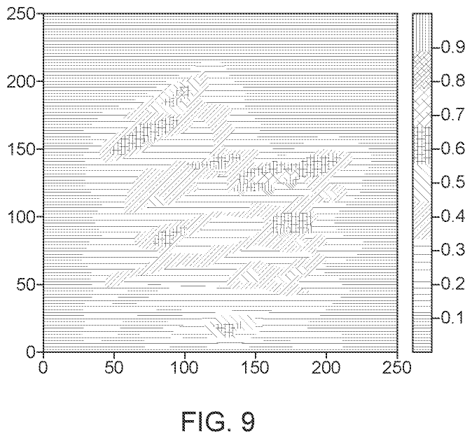

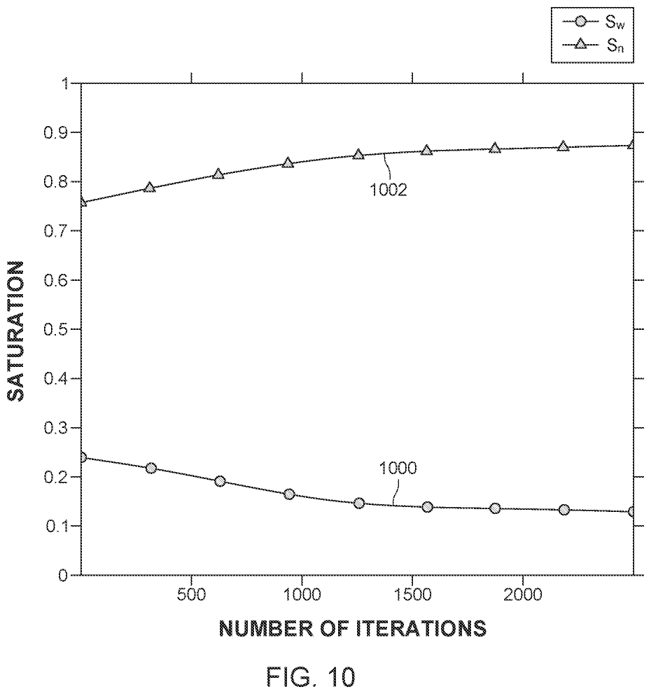

To appreciate the capabilities of the P-IMPES method versus the conventional HF-IMPES scheme, the saturations of the wetting phase at the time step 2,400 were calculated for the case of B_{c}=1 and they are shown in FIG. 9. It is noted that some values of the wetting phase saturation are reduced by one due to the fact that these values are larger than the one based on the HF-IMPES scheme. FIG. 10 shows that the mass-conservation property does not hold well for this case based on the conventional HF-IMPES scheme, as the wetting phase S_{w} indicated by curve 1000 in FIG. 10 and the non-wetting phase Sₙ indicated by curve 1002 in the same figure are not flat.

Thus, the physics-preserving P-IMPES method discussed above better simulates an incompressible and immiscible two-phase flow in heterogeneous porous media with capillary pressure. The new method relies on one or more of the following features: rewrite the Darcy flows for both phases in the formulation based on the total velocity and an auxiliary velocity referring to as the capillary potential gradient, and obtains the total conservation equation by summing the discretized conservation equation for each phase. It was found that the new P-IMPES scheme is locally mass-conservative for both phases and it also retains the desired property that the total velocity is continuous in its normal direction. Another merit of the new method is that is unbiased with regard to the two phases and the saturation of each phase is bounds-preserving when the time step size is small enough. For the numerical experiments that have been discussed above, it was shown that the proposed scheme always holds the mass-conservation property.

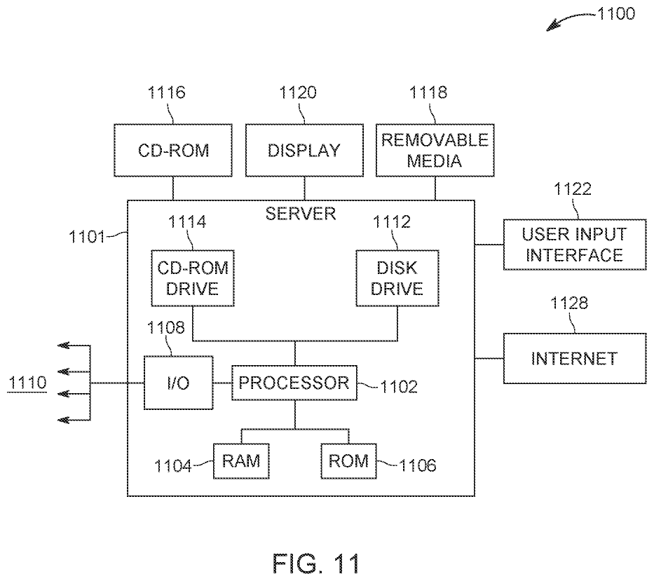

The above-discussed schemes and methods may be implemented in a computing device as illustrated in FIG. 11. Hardware, firmware, software or a combination thereof may be used to perform the various steps and operations described herein.

A computing device 1100 suitable for performing the activities described in the above embodiments may include a server 1101. Such a server 1101 may include a central processor (CPU) 1102 coupled to a random access memory (RAM) 1104 and to a read-only memory (ROM) 1106. ROM 1106 may also be other types of storage media to store programs, such as programmable ROM (PROM), erasable PROM (EPROM), etc. Processor 1102 may communicate with other internal and external components through input/output (I/O) circuitry 1108 and bussing 1110 to provide control signals and the like. Processor 1102 carries out a variety of functions as are known in the art, as dictated by software and/or firmware instructions.

Server 1101 may also include one or more data storage devices, including hard drives 1112, CD-ROM drives 1114 and other hardware capable of reading and/or storing information, such as DVD, etc. In one embodiment, software for carrying out the above-discussed steps may be stored and distributed on a CD-ROM or DVD 1116, a USB storage device 1118 or other form of media capable of portably storing information. These storage media may be inserted into, and read by, devices such as CD-ROM drive 1114, disk drive 1112, etc. Server 1101 may be coupled to a display 1120, which may be any type of known display or presentation screen, such as LCD, plasma display, cathode ray tube (CRT), etc. A user input interface 1122 is provided, including one or more user interface mechanisms such as a mouse, keyboard, microphone, touchpad, touch screen, voice-recognition system, etc.

Server 1101 may be coupled to other devices, such as sources, detectors, etc. The server may be part of a larger network configuration as in a global area network (GAN) such as the Internet 1128, which allows ultimate connection to various landline and/or mobile computing devices.

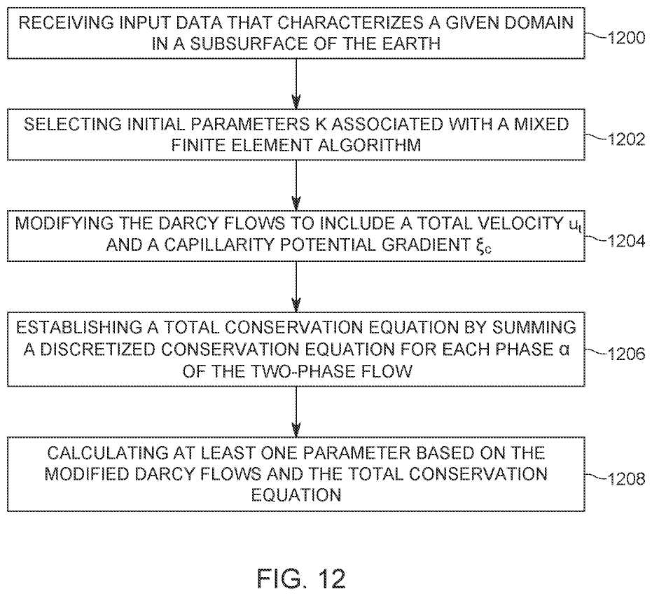

A physics-preserving implicit pressure explicit saturation method for simulation of incompressible and immiscible two-phase flow in heterogeneous porous media with capillary pressure is now discussed with regard to FIG. 12. The method is based on the equations discussed above. The method includes a step 1200 of receiving input data that characterizes a given domain in a subsurface of the earth, a step 1202 of selecting initial parameters K associated with a mixed finite element algorithm, a step 1204 of modifying the Darcy flows to include a total velocity uₜ and a capillarity potential gradient ξ_{c}, a step 1206 of establishing a total conservation equation by summing a discretized conservation equation for each phase a of the two-phase flow, and a step 1208 of calculating at least one parameter based on the modified Darcy flows and the total conservation equation. The at least one parameter characterizes the two-phase flow in the heterogeneous porous media with a capillary pressure.

In one embodiment, the at least one parameter includes one or more of a saturation for each phase, pressure for each phase, or the total velocity of the flow. In the same or another embodiment, the input data includes at least one of a porosity, density, relative permeability, viscosity, depth, gravity, or capillary pressure of the given domain. In still the same or another embodiment, the initial parameters include a number of elements and a shape of the elements that define the given domain.

The method may further include a step of discretizing the Darcy flows and the total conservation equation, and/or a step of linearizing the discretized Darcy flows and the total conservation equation. The two-phase flow has two phases, a wetting phase and a non-wetting phase. In one application, the wetting phase is associated with water and the non-wetting phase is associated with oil. In still another application, the Darcy flows include the capillary pressure. In yet another application, there are two Darcy flows, and a single total conservation equation.

The disclosed embodiments provide a physics-preserving IMplicit Pressure Explicit Saturation scheme for the simulation of incompressible and immiscible two-phase flow in heterogeneous porous media with capillary pressure. While the new P-IMPES method may be applied in many practical fields, the examples discussed above are specifically adapted to oil and gas reservoir characterization, and more specifically, to calculating a flow of the oil and/or water in the subsurface (i.e., underground) through a porous medium. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

[1] R. Adams, Sobolev Spaces, Academic Press, New York, 1975.
[2] E. Abreu, J. Douglas, F. Furtado, and F. Pereira, Operator splitting for three-phase flow in heterogeneous porous media, Commun. Comput. Phys., 6 (2009), pp. 72-84.
[3] U. Ascher, S. J. Ruuth, and B. T. R. Wetton, Implicit-explicit methods for time-dependent partial differential equations, SIAM J. Numer. Anal., 32 (1995), pp. 797-823.
[4] K. Aziz and A. Settari, Petroleum Reservoir Simulation, London: Applied Science Pub., 1979.
[5] C. Bahriawati, C. Carstensen, Three MATLAB implementations of the lowest-order Raviart-Thomas MFEM with a posteriori error control, Comput. Methods Appl. Math., 5 (2005), pp. 333-361.
[6] F. Brezzi and M. Fortin, Mixed and Hybrid Finite Element Methods, Springer, NewYork, 1991.
[7] Z. Chen, G. Huan, and B. Li, An improved IMPES method for two-phase flow in porous media, Transp. Porous Media, 54(2004), pp. 361-376.
[8] Z. Chen, G. Huan, and Y. Ma, Computational methods for multiphase flows in porous media, SIAM, Philadelphia, Pa., USA, 2006.
[9] K. H. Coats, A note on IMPES and some IMPES-based simulation models, Presented at the 15th symposium on reservoir simulation, Houston, Tex., 1999, SPE 49774.
[10] K. H. Coats, IMPES stability: the CFL limit, Presented at the SPE reservoir simulation symposium, Houston, Tex., 2001, SPE 85956.
[11] K. H. Coats, IMPES stability: selection of stable time steps, Presented at the SPE reservoir simulation symposium, Houston, Tex., 2001, SPE 84924.
[12] D. A. Collins, L. X. Nghiem, Y. K. Li, and J. E. Grabenstetter, An efficient approach to adaptive implicit compositional simulation with an equation of state, SPE Reservoir Eng., 7(1992), pp. 259-264.
[13] C. N. Dawson, H. Klie, M. F. Wheeler, and C. S. Woodward, A parallel, implicit, cell-centered method for two-phase flow with a preconditioned Newton-Krylov solver, Comput. Geosci., 1 (1997), pp. 215-249.
[14] R. G. Fagin and Jr. C. H. Stewart, A new approach to the two-dimensional multiphase reservoir simulator, SPE J., 1966, SPE 1188.
[15] H. Hoteit and A. Firoozabadi, Numerical modeling of two-phase flow in heterogeneous permeable media with different capillarity pressures, Adv. Water Resour., 31 (2008), pp. 56-73.
[16] H. Hoteit and A. Firoozabadi, An efficient numerical model for incompressible two-phase flow in fractured media, Adv. Water Resour., 31 (2008), pp. 891-905.
[17] J. E. P. Monteagudo and A. Firoozabadi, Comparison of fully implicit and IMPES formulations for simulation of water injection in fractured and unfractured media, Int. J. Numer. Meth. Eng., 69 (2007), pp. 698-728.
[18] J. W. Sheldon, B. Zondek, and W. T. Cardwell, One-dimensional, incompressible, noncapillary, two-phase fluid flow in a porous medium, T. SPE AIME, 216 (1959), pp. 290-296.
[19] H. L. Stone and A. O. Garder Jr., Analysis of gas-cap or dissolved-gas reservoirs, T. SPE AIME, 222 (1961), pp. 92-104.
[20] G. W. Thomas and D. H. Thurnau, Reservoir simulation using an adaptive implicit method, SPE J., 23 (1983), pp. 759-768.
[21] J. W. Watts, A compositional formulation of the pressure and saturation equations, 1985, SPE 12244.
[22] Y. Wu and G. Qin, A generalized numerical approach for modeling multiphase flow and transport in fractured porous media, Commun. Comput. Phys., 6 (2009), pp. 85-108.
[23] H. Yang, S. Sun, C. Yang, Nonlinearly preconditioned semismooth Newton methods for variational inequality solution of two-phase flow in porous media, J. Comput. Phys., 332 (2017), 1-20.
[24] H. Yang, C. Yang, S. Sun, Active-set reduced-space methods with nonlinear elimination for two-phase flow problems in porous media, SIAM J. Sci. Comput., 38 (2016), B593-B618.
[25] H. Yang, S. Sun, Y. Li, and C. Yang, A scalable fully implicit framework for reservoir simulation on parallel computers, Comput. Methods Appl. Mech. Engrg., 330 (2018), pp. 334-350.
[26] L. C. Young and R. E. Stephenson, A generalized compositional approach for reservoir simulation, SPE J., 23 (1983), pp. 727-742.
[27] A. Zidane and A. Firoozabadi, An implicit numerical model for multicomponent compressible two-phase ow in porous media, Adv. Water Resour., 85 (2015), pp. 64-78.

1. A physics-preserving implicit pressure explicit saturation method for simulation of incompressible and immiscible two-phase flow in heterogeneous porous media with capillary pressure, the method comprising:
receiving input data that characterizes a given domain in a subsurface of the earth;
selecting initial parameters K associated with a mixed finite element algorithm;
modifying Darcy flows to include a total velocity uₜ and a capillarity potential gradient ξ_{c};
establishing a total conservation equation by summing a discretized conservation equation for each phase α of the two-phase flow; and
calculating at least one parameter based on the modified Darcy flows and the total conservation equation,
wherein the at least one parameter characterizes the two-phase flow in the heterogeneous porous media with a capillary pressure, between an injection well and a production well.

2. The method of claim 1, wherein the at least one parameter includes one or more of a saturation for each phase, a pressure for each phase, or the total velocity of the flow.

3. The method of claim 1, wherein the input data includes at least one of a porosity, density, relative permeability, viscosity, depth, gravity, or capillary pressure of the given domain.

4. The method of claim 1, wherein the initial parameters include a number of elements and a shape of the elements that define the given domain.

5. The method of claim 1, further comprising:
discretizing the Darcy flows and the total conservation equation.

6. The method of claim 5, further comprising:
linearizing the discretized Darcy flows and the total conservation equation.

7. The method of claim 1, wherein the two-phase flow has two phases, a wetting phase and a non-wetting phase.

8. The method of claim 7, wherein the wetting phase is associated with water and the non-wetting phase is associated with oil.

9. The method of claim 1, wherein the Darcy flows include the capillary pressure.

10. The method of claim 1, wherein there are two Darcy flows, and a single total conservation equation.

11. A computing device for implementing a physics-preserving implicit pressure explicit saturation method for simulation of incompressible and immiscible two-phase flow in heterogeneous porous media with capillary pressure, the computing device comprising:
an input/output interface for receiving input data that characterizes a given domain in a subsurface of the earth; and
a processor connected to the input/output interface and configured to,
select initial parameters K associated with a mixed finite element algorithm,
modify Darcy flows to include a total velocity uₜ and a capillarity potential gradient ξ_{c},
establish a total conservation equation by summing a discretized conservation equation for each phase a of the two-phase flow, and
calculate at least one parameter based on the modified Darcy flows and the total conservation equation,
wherein the at least one parameter characterizes the two-phase flow in the heterogeneous porous media with a capillary pressure, between an injection well and a production well.

12. The computing device of claim 11, wherein the at least one parameter includes one or more of a saturation for each phase, a pressure for each phase, or the total velocity of the flow, the input data includes at least one of a porosity, density, relative permeability, viscosity, depth, gravity, or capillary pressure of the given domain, and the initial parameters include a number of elements and a shape of the elements that define the given domain.

13. The computing device of claim 11, wherein the processor is further configured to:
discretize the Darcy flows and the total conservation equation.

14. The computing device of claim 13, wherein the processor is further configured to:
linearize the discretized Darcy flows and the total conservation equation.

15. The computing device of claim 11, wherein the two-phase flow has two phases, a wetting phase and a non-wetting phase.

16. The computing device of claim 15, wherein the wetting phase is associated with water and the non-wetting phase is associated with oil.

17. The computing device of claim 11, wherein the Darcy flows include the capillary pressure.

18. A physics-preserving implicit pressure explicit saturation method for simulation of incompressible and immiscible two-phase flow in heterogeneous porous media with capillary pressure, the method comprising:
receiving input data that characterizes a given domain in a subsurface of the earth;
selecting initial parameters K associated with a mixed finite element algorithm;
modifying Darcy flows to include a total velocity uₜ and a capillarity potential gradient ξ_{c};
establishing a total conservation equation by summing a discretized conservation equation for each phase α of the two-phase flow; and
calculating at least one parameter based on the modified Darcy flows and the total conservation equation.

19. The method of claim 18, wherein the at least one parameter characterizes the two-phase flow in the heterogeneous porous media with a capillary pressure, and the Darcy flows include the capillary pressure.

20. The method of claim 18, wherein the at least one parameter includes one or more of a saturation for each phase, pressure for each phase, or the total velocity of the flow, the input data includes at least one of a porosity, density, relative permeability, viscosity, depth, gravity, or capillary pressure of the given domain, and the initial parameters include a number of elements and a shape of the elements that define the given domain.
